(19) United States
(12) Patent Application Publication
(10) Pub. No.: US 2023/0307225 A1
(43) Pub. Date: Sep. 28, 2023

(54) METHOD OF PROCESSING SUBSTRATE, METHOD OF MANUFACTURING SEMICONDUCTOR DEVICE, RECORDING MEDIUM, AND SUBSTRATE PROCESSING APPARATUS

(71) Applicant: Kokusai Electric Corporation, Tokyo (JP)

(72) Inventor: Masaya NISHIDA, Toyama-shi (JP)

(73) Assignee: Kokusai Electric Corporation, Tokyo (JP)

(21) Appl. No.: 18/188,077

(22) Filed: Mar. 22, 2023

(30) Foreign Application Priority Data
Mar. 24, 2022 (JP) 2022-047955

(51) Int. Cl. H01L 21/02; H01L 21/67

(52) U.S. Cl. CPC H01L 21/0214; H01L 21/022; H01L 21/02233; H01L 21/67017

(57) ABSTRACT

Provided is a technique including: (a) a step of forming a laminated film formed by laminating a first film containing nitrogen, oxygen, and a predetermined element and a second film containing nitrogen and having a composition different from that of the first film on a substrate in a processing container; and (b) modifying the first film and the second film adhering to an inside of the processing container in (a) to bring the composition of the second film close to the composition of the first film.

### CROSS-REFERENCE TO RELATED APPLICATIONS

This application is based upon and claims the benefit of priority from Japanese Patent Application No. 2022-047955, filed on Mar. 24, 2022, the entire contents of which are incorporated herein by reference.

### TECHNICAL FIELD

The present disclosure relates to a method of processing a substrate, a method of manufacturing a semiconductor device, a recording medium, and a substrate processing apparatus.

### DESCRIPTION OF THE RELATED ART

In related art, as one step of a process of manufacturing a semiconductor device, a step of forming a laminated film formed by laminating a first film and a second film on a substrate in a processing container may be performed.

### SUMMARY

However, when the laminated film is formed on the substrate, the laminated film may also be formed in the processing container and adhere to the inside of the processing container, and film peeling may occur due to a difference in film stress between the first film and the second film in the laminated film adhering to the inside of the processing container.

Some embodiments of the present disclosure provide a technique capable of suppressing occurrence of film peeling of the laminated film adhering to the inside of the processing container.

According to some embodiments of the present disclosure provide a technique including:
(a) forming a laminated film formed by laminating a first film containing nitrogen, oxygen, and a predetermined element and a second film containing nitrogen and having a composition different from that of the first film on a substrate in a processing container; and
(b) modifying the first film and the second film adhering to an inside of the processing container in (a) to bring the composition of the second film adhering to the inside of the processing container close to the composition of the first film adhering to the inside of the processing container.

### BRIEF DESCRIPTION OF THE DRAWINGS

FIG. 1 is a schematic configuration diagram of a vertical processing furnace of a substrate processing apparatus preferably used in some embodiments of the present disclosure, and is a longitudinal cross-sectional view of a processing furnace.

FIG. 2 is a schematic configuration diagram of the vertical processing furnace of the substrate processing apparatus preferably used in some embodiments of the present disclosure, and is a cross-sectional view of the processing furnace taken along line A-A.

FIG. 3 is a schematic configuration diagram of a controller of the substrate processing apparatus preferably used in some embodiments of the present disclosure, and is a block diagram illustrating a control system of the controller.

FIG. 4 is a diagram illustrating a flow of a substrate processing process in some embodiments of the present disclosure.

FIG. 5 is a diagram illustrating an example of a processing sequence of a first film in some embodiments of the present disclosure.

FIG. 6 is a diagram illustrating an example of a processing sequence of a second film in some embodiments of the present disclosure.

FIG. 7A is a partially enlarged cross-sectional view of a surface of a wafer. FIG. 7B is a partially enlarged cross-sectional view of the surface of the wafer after the first film is formed on the wafer. FIG. 7C is a partially enlarged cross-sectional view of the surface of the wafer after the second film is formed on the first film.

FIG. 8 is a partially enlarged cross-sectional view of an inner wall of a processing container to which a laminated film formed by alternately laminating the first film and the second film adheres.

FIG. 9 is a diagram illustrating measurement results of a film stress of each film in the laminated film.

### DETAILED DESCRIPTION

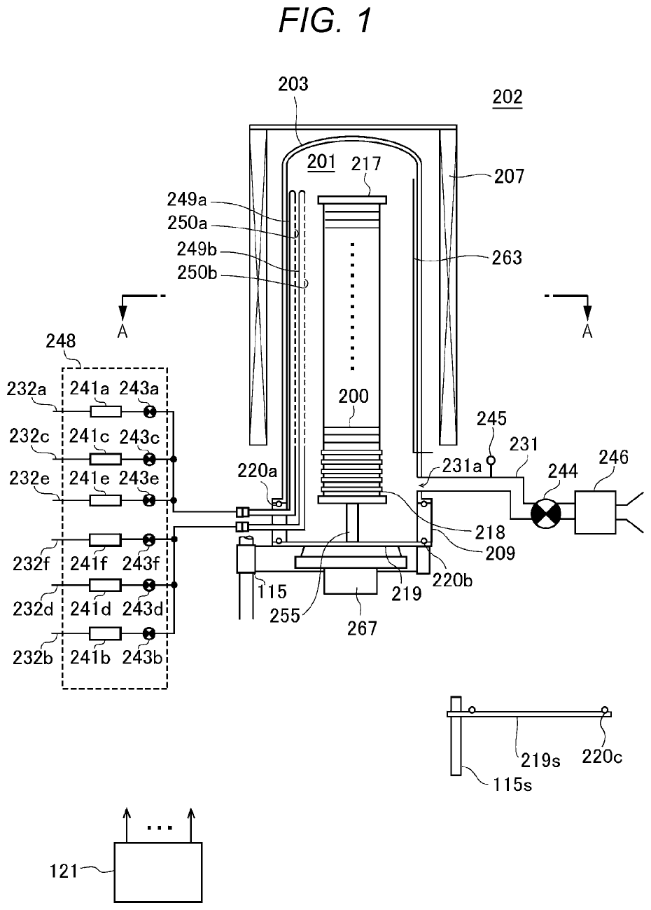

Hereinafter, embodiments of the present disclosure will be described mainly with reference to FIGS. 1 to 8. Note that the drawings used in the following description are all schematic, and a dimensional relationship among elements, a ratio among the elements, and the like illustrated in the drawings do not necessarily coincide with actual ones. In addition, a dimensional relationship among elements, a ratio among the elements, and the like do not necessarily coincide among the plurality of drawings.

Configuration of Substrate Processing Apparatus

As illustrated in FIG. 1, a processing furnace 202 includes a heater 207 serving as a temperature regulator (heater). The heater 207 has a cylindrical shape, and is vertically installed by being supported by a holding plate. The heater 207 also functions as an activation mechanism (thermal exciter) that activates (excites) a gas with heat.

Inside the heater 207, a reaction tube 203 is disposed concentrically with the heater 207. The reaction tube 203 is formed of a heat-resistant material such as quartz (SiO₂) or silicon carbide (SiC), and is formed in a cylindrical shape with an upper end closed and a lower end opened. A manifold 209 is disposed below the reaction tube 203 concentrically with the reaction tube 203. The manifold 209 is formed of a metal material such as stainless steel (SUS), and is formed in a cylindrical shape with an upper end and a lower end opened. The upper end portion of the manifold 209 is engaged with the lower end portion of the reaction tube 203 and is configured to support the reaction tube 203. An O-ring 220a serving as a seal member is disposed between the manifold 209 and the reaction tube 203. The reaction tube 203 is vertically installed similarly to the heater 207. A processing container (reaction container) is constituted mainly by the reaction tube 203 and the manifold 209. A processing chamber 201 is formed in a cylindrical hollow portion of the processing container. The processing chamber 201 is configured to be able to house a wafer 200 serving as a substrate. Processing is performed on the wafer 200 in the processing chamber 201, that is, in the processing container.

In the processing chamber 201, nozzles 249a and 249b serving as first and second suppliers are disposed so as to pass through a side wall of the manifold 209. The nozzles 249a and 249b are also referred to as a first nozzle and a second nozzle, respectively. The nozzles 249a and 249b are formed of a heat-resistant material such as quartz or SiC. Gas supply pipes 232a and 232b are connected to the nozzles 249a and 249b, respectively. The nozzles 249a and 249b are different nozzles, and are disposed adjacent to each other.

In the gas supply pipes 232a and 232b, mass flow controllers (MFCs) 241a and 241b that are flow rate controllers and valves 243a and 243b that are on-off valves are disposed in this order from an upstream side of a gas flow, respectively. Gas supply pipes 232c and 232e are connected to a downstream side of the valve 243a of the gas supply pipe 232a. Gas supply pipes 232d and 232f are connected to a downstream side of the valve 243b of the gas supply pipe 232b. In the gas supply pipes 232c to 232f, MFCs 241c to 241f and valves 243c to 243f are disposed in this order from an upstream side of a gas flow, respectively. The gas supply pipes 232a to 232f are formed of a metal material such as SUS.

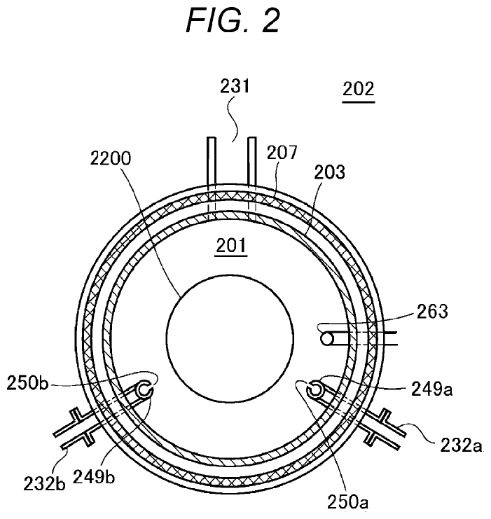

As illustrated in FIGS. 1 and 2, the nozzles 249a and 249b are disposed in an annular space in plan view between an inner wall of the reaction tube 203 and the wafers 200 so as to rise upward in an arrangement direction of the wafers 200 from a lower portion of the inner wall of the reaction tube 203 to an upper portion thereof along the inner wall. That is, the nozzles 249a and 249b are disposed along a wafer arrangement region where the wafers 200 are arranged in a region horizontally surrounding the wafer arrangement region on a lateral side of the wafer arrangement region. Each of gas supply holes 250a and 250b is open toward the center of the wafer 200 in plan view, a gas can be supplied toward the wafer 200. A plurality of the gas supply holes 250a and a plurality of the gas supply holes 250b are formed from a lower portion of the reaction tube 203 to an upper portion thereof.

From the gas supply pipe 232a, a source gas containing a semiconductor element or a metal element is supplied into the processing chamber 201 via the MFC 241a, the valve 243a, and the nozzle 249a.

From the gas supply pipe 232b, an oxygen (O)-containing gas is supplied into the processing chamber 201 via the MFC 241b, the valve 243b, and the nozzle 249b.

From the gas supply pipe 232c, a predetermined element-containing gas containing at least one of carbon (C) and boron (B) is supplied into the processing chamber 201 via the MFC 241c, the valve 243c, and the nozzle 249a.

From the gas supply pipe 232d, a nitrogen (N)-containing gas is supplied into the processing chamber 201 via the MFC 241d, the valve 243d, and the nozzle 249b.

From the gas supply pipes 232e and 232f, an inert gas is supplied into the processing chamber 201 via the MFCs 241e and 241f, the valves 243e and 243f, the gas supply pipes 232a and 232b, and the nozzles 249a and 249b, respectively. The inert gas acts as a purge gas, a carrier gas, a diluent gas, or the like.

A processing gas supply system (a source gas supply system, a nitrogen-containing gas supply system, an oxygen-containing gas supply system, and a predetermined element-containing gas supply system) is constituted mainly by the gas supply pipes 232a to 232d, the MFCs 241a to 241d, and the valves 243a to 243d. An inert gas supply system is constituted mainly by the gas supply pipes 232e and 232f, the MFCs 241e and 241f, and the valves 243e and 243f.

Any or all of the various gas supply systems described above may be constituted as an integrated gas supply system 248 in which the valves 243a to 243f, the MFCs 241a to 241f, and the like are integrated. The integrated gas supply system 248 is connected to each of the gas supply pipes 232a to 232f, and is configured such that an operation of supplying various gases into the gas supply pipes 232a to 232f, that is, opening and closing operations of the valves 243a to 243f, flow rate regulating operations of the MFCs 241a to 241f, and the like are controlled by a controller 121 described later. The integrated gas supply system 248 is configured as an integrated or divided integrated unit, and is configured to be capable of being attached to and detached from the gas supply pipes 232a to 232f and the like in units of integrated units and to be capable of performing maintenance, replacement, expansion, and the like of the integrated gas supply system 248 in units of integrated units.

An exhaust port 231a that exhausts the atmosphere inside the processing chamber 201 is formed below a side wall of the reaction tube 203. The exhaust port 231a may be formed from a lower portion of the side wall of the reaction tube 203 to an upper portion thereof along the side wall, that is, along the wafer arrangement region. An exhaust pipe 231 is connected to the exhaust port 231a. To the exhaust pipe 231, a vacuum pump 246 serving as a vacuum exhauster is connected via a pressure sensor 245 serving as a pressure detector (pressure detecting unit) to detect a pressure inside the processing chamber 201 and an auto pressure controller (APC) valve 244 serving as a pressure regulator (pressure regulating unit). The APC valve 244 is a valve configured to be capable of performing vacuum exhaust and stopping the vacuum exhaust inside the processing chamber 201 by opening/closing a valve in a state where the vacuum pump 246 is operated, and to be capable of regulating a pressure inside the processing chamber 201 by adjusting the degree of valve opening based on pressure information detected by the pressure sensor 245 in a state where the vacuum pump 246 is operated. An exhaust system is formed mainly by the exhaust pipe 231, the APC valve 244, and the pressure sensor 245. The vacuum pump 246 may also be included in the exhaust system.

A seal cap 219 serving as a furnace opening lid capable of hermetically closing a lower end opening of the manifold 209 is disposed below the manifold 209. The seal cap 219 is formed of a metal material such as SUS, and is formed in a disk shape. An O-ring 220b serving as a seal member in contact with a lower end of the manifold 209 is disposed on an upper surface of the seal cap 219. A rotation mechanism 267 that rotates a boat 217 described later is disposed below the seal cap 219. A rotating shaft 255 of the rotation mechanism 267 is formed of a metal material such as SUS, passes through the seal cap 219, and is connected to the boat 217. The rotation mechanism 267 is configured to rotate the wafer 200 by rotating the boat 217. The seal cap 219 is configured to be raised and lowered in the vertical direction by a boat elevator 115 serving as a raising/lowering mechanism disposed outside the reaction tube 203. The boat elevator 115 is configured as a carry device (carry mechanism) that loads the wafer 200 into the processing chamber 201 and unloads the wafer 200 out of the processing chamber 201 (carry) by raising and lowering the seal cap 219.

Below the manifold 209, a shutter 219s serving as a furnace opening lid capable of hermetically closing a lower end opening of the manifold 209 is disposed in a state where the seal cap 219 is lowered and the boat 217 is unloaded from the inside of the processing chamber 201. The shutter 219s is formed of a metal material such as SUS, and is formed in a disk shape. An O-ring 220c serving as a seal member in contact with a lower end of the manifold 209 is disposed on an upper surface of the shutter 219s. An opening/closing operation (a raising/lowering operation, a rotation operation, or the like) of the shutter 219s is controlled by a shutter opening/closing mechanism 115s.

The boat 217 serving as a substrate support (substrate retainer) is configured to support a plurality of, for example, 25 to 200 wafers 200 in multiple stages while the wafers 200 are arranged in the vertical direction in a horizontal posture and in a state where the centers thereof are aligned with each other. That is, the boat 217 is configured such that the plurality of wafers 200 are arranged at intervals in the vertical direction in a horizontal posture. The boat 217 is formed of a heat-resistant material such as quartz or SiC. In a lower portion of the boat 217, heat insulating plates 218 formed of a heat-resistant material such as quartz or SiC are supported in multiple stages. The boat 217 is configured to be capable of supporting each of the plurality of wafers 200.

A temperature sensor 263 serving as a temperature detector is disposed in the reaction tube 203. By adjusting a degree of energization to the heater 207 based on temperature information detected by the temperature sensor 263, the temperature in the processing chamber 201 has a desired temperature distribution. The temperature sensor 263 is disposed along an inner wall of the reaction tube 203.

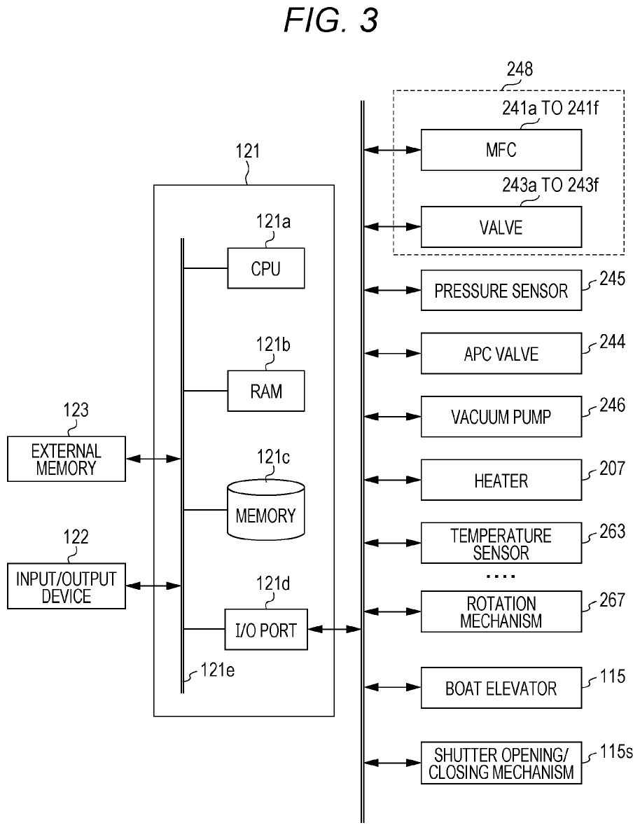

As illustrated in FIG. 3, the controller 121 is configured as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus 121e. To the controller 121, an input/output device 122 configured as, for example, a touch panel is connected. An external memory 123 can be connected to the controller 121.

The memory 121c is constituted by, for example, a flash memory, a hard disk drive (HDD), or a solid state drive (SSD). In the memory 121c, a control program that controls an operation of the substrate processing apparatus, a process recipe in which processing procedures, processing conditions, and the like described later are described, and the like are stored to be readable. The process recipe is a combination formed such that the controller 121 causes the substrate processing apparatus to execute each procedure in processing described later to obtain a predetermined result, and functions as a program. Hereinafter, the process recipe, the control program, and the like are also collectively and simply referred to as a program. The process recipe is also simply referred to as a recipe. In the present specification, the term “program” may include only the recipe alone, only the control program alone, or both. The RAM 121b is configured as a memory area (work area) in which programs, data, and the like read by the CPU 121a are temporarily stored.

The I/O port 121d is connected to the MFCs 241a to 241f, the valves 243a to 243f, the pressure sensor 245, the APC valve 244, the vacuum pump 246, the temperature sensor 263, the heater 207, the rotation mechanism 267, the boat elevator 115, the shutter opening/closing mechanism 115s, and the like described above.

The CPU 121a is configured to be capable of reading the control program from the memory 121c and executing the control program, and reading the recipe from the memory 121c in response to an input or the like of an operation command from the input/output device 122. The CPU 121a is configured to be capable of controlling flow rate regulating operations of various gases by the MFCs 241a to 241g, opening/closing operations of the valves 243a to 243g, an opening/closing operation of the APC valve 244, a pressure regulating operation by the APC valve 244 based on the pressure sensor 245, start and stop of the vacuum pump 246, a temperature regulating operation of the heater 207 based on the temperature sensor 263, operations of adjusting rotation and rotation speed of the boat 217 by the rotation mechanism 267, a raising/lowering operation of the boat 217 by the boat elevator 115, an opening/closing operation of the shutter 219s by the shutter opening/closing mechanism 115s, and the like according to the contents of the read recipe.

The controller 121 can be configured by installing the above-described program stored in the external memory 123 into the computer. Examples of the external memory 123 include a magnetic disk such as an HDD, an optical disk such as a CD, a magneto-optical disk such as an MO, and a semiconductor memory such as a USB memory or an SSD. The memory 121c and the external memory 123 are configured as computer-readable recording media. Hereinafter, these are collectively and simply referred to as a recording medium. In the present specification, the term “recording medium” may include only the memory 121c alone, only the external memory 123 alone, or both. Note that the program may be provided to the computer by using a communication means such as the Internet or a dedicated line without using the external memory 123.

(2) Substrate Processing Step

An example of a processing sequence of forming a laminated film formed by laminating a first film and a second film on the wafer 200 serving as a substrate in a processing container and performing modification of bringing the composition of the second film in the laminated film adhering to the inside of the processing container close to the composition of the first film will be described as one step of a process of manufacturing a semiconductor device using the above-described substrate processing apparatus. In the following description, operations of the units constituting the substrate processing apparatus are controlled by the controller 121.

In the processing sequence in the present embodiments, step A of forming a laminated film formed by laminating a first film containing N, O, and a predetermined element and a second film containing N and having a composition different from that of the first film on the wafer 200 in a processing container; and step B of modifying the laminated film (that in, lamination of the first film and the second film) adhering to an inside of the processing container in step A to bring the composition of the second film in the laminated film adhering to the inside of the processing container close to the composition of the first film in the laminated film adhering to the inside of the processing container are performed.

In the present embodiments, in step A, for example, a source gas, a N-containing gas, an O-containing gas, and a predetermined element-containing gas are supplied to form the first film on the wafer 200 (first film forming), and the source gas and the N-containing gas are supplied to form a second film (second film forming) to form a laminated film of the first film and the second film. Furthermore, in step B, for example, an O-containing gas is supplied to perform modification of bringing the composition of the second film in the laminated film adhering to the inside of the processing container close to the composition of the first film.

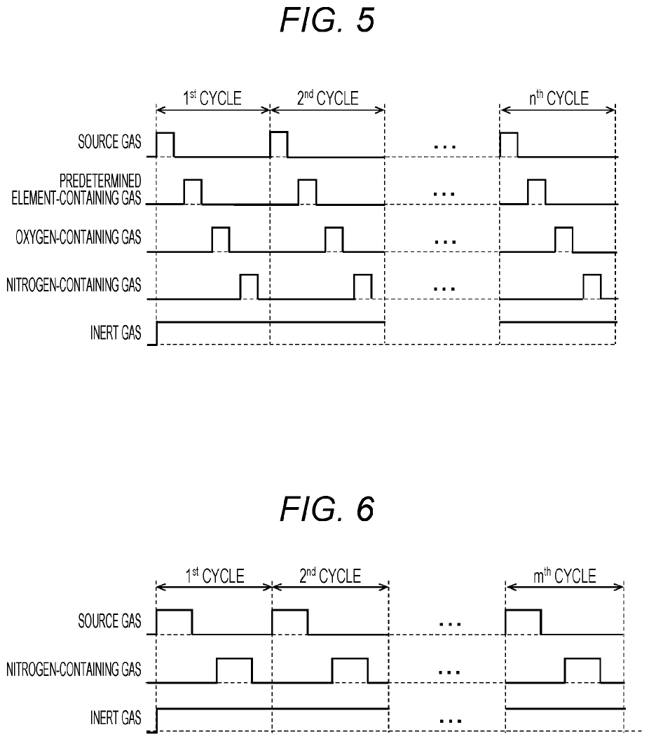

In the first film forming of step A in the present embodiments, as in the processing sequence illustrated in FIG. 5,

by performing a cycle of non-simultaneously performing

step A1 of supplying a source gas to the wafer 200 in the processing container,

step A2 of supplying a predetermined element-containing gas to the wafer 200 in the processing container,

step A3 of supplying an O-containing gas to the wafer 200 in the processing container, and

step A4 of supplying a N-containing gas to the wafers 200 in the processing container

a predetermined number of times (n times, n is an integer of 1 or more) to form the first film on the wafer 200.

In the second film forming of step A in the present embodiments, as in the processing sequence illustrated in FIG. 6,

by performing a cycle of non-simultaneously performing

step a1 of supplying a source gas to the wafer 200 in the processing container and

step a2 of supplying a N-containing gas to the wafer 200 in the processing container

a predetermined number of times (m times, m is an integer of 1 or more) to form the second film on the first film.

In the present specification, the above-described processing sequence may be expressed as follows for convenience. A similar expression will be used in the following description of other embodiments, modified examples, and the like.

First film forming: (source gas→predetermined element-containing gas→O-containing gas→N-containing gas)×n

Second film forming: (source gas→N-containing gas)×m

The term “wafer” used in the present specification may mean the wafer itself, or may mean a laminate of a wafer and a predetermined layer or film formed on a surface of the wafer. The term “surface of a wafer” used in the present specification may mean a surface of the wafer itself or a surface of a predetermined layer or the like formed on the wafer. In the present specification, the phrase “forming a predetermined layer on a wafer” means directly forming a predetermined layer on a surface of the wafer itself, or forming a predetermined layer on a layer or the like formed on the wafer. Use of the term “substrate” in the present specification is synonymous with use of the term “wafer”.

(2-1) Film Forming

First, a sequence example of the first film forming of forming the first film on the wafer 200 will be described, and next, a sequence example of the second film forming of forming the second film on the first film will be described.

(Wafer Charge)

The plurality of wafers 200 is charged into the boat 217 (wafer charge). Thereafter, the shutter 219s is moved by the shutter opening/closing mechanism 115s, and the lower end opening of the manifold 209 is opened (shutter open).

(Boat Load)

Thereafter, as illustrated in FIG. 1, the boat 217 supporting the plurality of wafers 200 is lifted up by the boat elevator 115 and is loaded into the processing chamber 201 (boat load). In this state, the seal cap 219 seals the lower end of the manifold 209 via the O-ring 220b.

(Pressure Regulating and Temperature Regulating)

After the boat load is completed, the inside of the processing chamber 201, that is, a space where the wafers 200 are present is vacuum-exhausted (decompression-exhausted) by the vacuum pump 246 so as to have a desired pressure (degree of vacuum). At this time, a pressure in the processing chamber 201 is measured by the pressure sensor 245, and the APC valve 244 is feedback-controlled based on the measured pressure information (pressure regulating). The wafers 200 in the processing chamber 201 are heated by the heater 207 so as to have a desired processing temperature. At this time, a degree of energization to the heater 207 is feedback-controlled based on temperature information detected by the temperature sensor 263 such that the inside of the processing chamber 201 has a predetermined temperature distribution (temperature regulating). Rotation of the wafers 200 by the rotation mechanism 267 is started. The operation of the vacuum pump 246 and the heating and rotation of the wafers 200 are continuously performed at least until the processing for the wafers 200 is completed.

(First Film Forming)

Thereafter, the following steps A1 to A4 are sequentially executed.

[Step A1]

In step A1, a source gas is supplied to the wafers 200 in the processing chamber 201.

Specifically, the valve 243a is opened to cause the source gas to flow into the gas supply pipe 232a. A flow rate of the source gas is regulated by the MFC 241a, and the source gas is supplied into the processing chamber 201 via the nozzle 249a and exhausted from the exhaust port 231a. At this time, the source gas is supplied to the wafers 200 from a lateral side of the wafers 200 (source gas supply). At this time, the valves 243e and 243f are opened to supply an inert gas into the processing chamber 201 via the nozzles 249a and 249b, respectively. Note that, in some methods described below, the supply of the inert gas into the processing chamber 201 may be omitted.

As processing conditions in this step,

processing temperature: 250 to 800° C., preferably 400 to 700° C.

processing pressure: 1 to 2666 Pa, preferably 67 to 1333 Pa,

source gas supply flow rate: 0.01 to 2 slm, preferably 0.1 to 1 slm,

source gas supply time: 1 to 120 seconds, preferably 1 to 60 seconds, and

inert gas supply flow rate (per gas supply pipe): 0 to 10 slm are exemplified.

Note that expression of a numerical range such as “250 to 800° C.” in the present specification means that a lower limit value and an upper limit value are included in the range. Therefore, for example, “250 to 800° C.” means “250° C. or higher and 800° C. or lower”. The same applies to other numerical ranges. In the present specification, the processing temperature means a temperature of the wafer 200 or a temperature in the processing chamber 201, and the process pressure means a pressure in the processing chamber 201. The gas supply flow rate: 0 slm means a case where the gas is not supplied. The same applies to the following description.

By supplying, for example, a chlorosilane-based gas to the wafers 200 as the source gas under the above-described processing conditions, a Si-containing layer containing Cl is formed on an outermost surface of the wafers 200 serving as a base. The Si-containing layer containing Cl is formed on the outermost surface of the wafers 200 by physical adsorption or chemical adsorption of molecules of the chlorosilane-based gas, physical adsorption or chemical adsorption of molecules of a substance in which a part of the chlorosilane-based gas is decomposed, deposition of Si by thermal decomposition of the chlorosilane-based gas, or the like. The Si-containing layer containing Cl may be an adsorption layer (physical adsorption layer or chemical adsorption layer) of molecules of the chlorosilane-based gas or molecules of a substance in which a part of the chlorosilane-based gas is decomposed, or may be a deposited layer of Si containing Cl. In the present specification, the Si-containing layer containing Cl is also simply referred to as a Si-containing layer. Note that under the above-described processing conditions, physical adsorption or chemical adsorption of molecules of the chlorosilane-based gas or molecules of a substance in which a part of the chlorosilane-based gas is decomposed on the outermost surface of the wafers 200 occurs predominantly (preferentially), and deposition of Si due to thermal decomposition of the chlorosilane-based gas slightly occurs or hardly occurs. That is, under the above-described processing conditions, the Si-containing layer includes an adsorption layer (physical adsorption layer or chemical adsorption layer) of molecules of the chlorosilane-based gas or molecules of a substance in which a part of the chlorosilane-based gas is decomposed in an overwhelmingly large amount, and slightly or hardly includes a deposition layer of Si containing Cl.

After the Si-containing layer is formed, the valve 243a is closed, and the supply of the source gas into the processing chamber 201 is stopped. Then, the inside of the processing chamber 201 is vacuum-exhausted to remove a gas and the like remaining in the processing chamber 201 from the inside of the processing chamber 201. At this time, while the valves 243e and 243f are kept open, an inert gas is supplied into the processing chamber 201 and exhausted from the exhaust port 231a, and the inside of the processing chamber 201 is purged with the inert gas (purge).

As processing conditions in the purge, processing pressure: 1 to 20 Pa,

inert gas supply flow rate (per gas supply pipe): 0.05 to 20 slm, and

inert gas supply time: 1 to 200 seconds, preferably 1 to 40 seconds

are exemplified. The other processing conditions are similar to the processing conditions at the time of supplying the source gas.

As the source gas, for example, a silane-based gas containing silicon (Si) serving as a main element constituting a film formed on the wafer 200 can be used. As the silane-based gas, for example, a gas containing a halogen and Si, that is, a halosilane-based gas can be used. The halogen includes chlorine (Cl), fluorine (F), bromine (Br), iodine (I), and the like. As the halosilane-based gas, for example, the above-described chlorosilane-based gas containing Cl and Si can be used.

As the source gas, for example, a chlorosilane-based gas such as a monochlorosilane (SiH₃Cl, abbreviation: MCS) gas, a dichlorosilane (SiH₂Cl₂, abbreviation: DCS) gas, a trichlorosilane (SiHCl₃, abbreviation: TCS) gas, a tetrachlorosilane (SiCl₄, abbreviation: 4CS) gas, a hexachlorodisilane gas (Si₂Cl₆, abbreviation: HCDS) gas, or an octachlorotrisilane

(Si₃Cl₈, Abbreviation: OCTS) Gas can be Used.

One or more of these gases can be used as the source gas.

As the source gas, in addition to the chlorosilane-based gas, for example, a fluorosilane-based gas such as a tetrafluorosilane (SiF₄) gas or a difluorosilane (SiH₂F₂) gas, a bromosilane-based gas such as a tetrabromosilane (SiBr₄) gas or a dibromosilane (SiH₂Br₂) gas, or an iodosilane-based gas such as a tetraiodosilane (Sil₄) gas or a diiodosilane (SiH₂I₂) gas can also be used. One or more of these gases can be used as the source gas.

As the source gas, in addition to these gases, for example, a gas containing an amino group and Si, that is, an aminosilane-based gas can also be used. The amino group is a monovalent functional group obtained by removing hydrogen (H) from ammonia, a primary amine, or a secondary amine, and can be represented as —NH₂, —NHR, or —NR₂. Note that R represents an alkyl group, and two Rs of —NR₂ may be the same or different.

As the source gas, for example, an aminosilane-based gas such as a tetrakis(dimethylamino) silane (Si[N(CH₃)₂]₄, abbreviation: 4DMAS) gas, a tris(dimethylamino) silane (Si[N(CH₃)₂]₃H, abbreviation: 3DMAS) gas, a bis(diethylamino) silane (Si[N(C₂H₅)₂]₂H₂, abbreviation: BDEAS) gas, a bis(tertiarybutylamino) silane (SiH₂[NH(C₄H₉)]₂, abbreviation: BTBAS) gas, or a (diisopropylamino) silane (SiH₃[N(C₃H₇)₂], abbreviation: DIPAS) gas can also be used. One or more of these gases can be used as the source gas.

The same applies to step a1 described later.

As the inert gas, for example, a rare gas such as a nitrogen (N₂) gas, an argon (Ar) gas, a helium (He) gas, a neon (Ne) gas, a xenon (Xe) gas, a krypton (Kr) gas, or a radon (Rn) gas can be used. One or more of these gases can be used as the inert gas. The same applies to each step described later.

[Step A2]

After step A1 is completed, a predetermined element-containing gas is supplied to the wafers 200 in the processing chamber 201, that is, to the Si-containing layer formed on the wafers 200.

Specifically, the valve 243c is opened to cause the predetermined element-containing gas to flow into the gas supply pipe 232c. A flow rate of the predetermined element-containing gas is regulated by the MFC 241c, and the predetermined element-containing gas is supplied into the processing chamber 201 via the nozzle 249a and exhausted from the exhaust port 231a. At this time, the predetermined element-containing gas is supplied to the wafers 200 from a lateral side of the wafers 200 (predetermined element-containing gas supply). At this time, while the valves 243e and 243f are kept open, an inert gas may be supplied into the processing chamber 201 via the nozzles 249a and 249b, respectively.

As processing conditions in this step,

processing pressure: 1 to 4000 Pa, preferably 1 to 3000 Pa,

predetermined element-containing gas supply flow rate: 0.1 to 10 slm, and

predetermined element-containing gas supply time: 1 to 120 seconds, preferably 1 to 60 seconds

are exemplified. The other processing conditions are similar to the processing conditions at the time of supplying the source gas in step A1.

For example, by supplying a carbon (C)-containing gas to the wafers 200 as the predetermined element-containing gas under the above-described conditions, at least a part of the Si-containing layer formed on the wafers 200 is carbonized (modified). As a result, on an outermost surface of the wafers 200 serving as a base, a silicon carbide layer (SiC layer) is formed as a layer formed by carbonizing the Si-containing layer, that is, as a layer containing Si and C. When the SiC layer is formed, impurities contained in the Si-containing layer, such as Cl, constitute a gaseous substance containing at least Cl in the process of the modification reaction of the Si-containing layer by the predetermined element-containing gas, and are discharged from the inside of the processing chamber 201. As a result, the SiC layer becomes a layer containing less impurities such as Cl than the Si-containing layer.

After the SiC layer is formed, the valve 243c is closed, the supply of the predetermined element-containing gas into the processing chamber 201 is stopped, and a gas and the like remaining in the processing chamber 201 are removed from the inside of the processing chamber 201 by processing procedures similar to the purge in step A1 (purge).

As the predetermined element-containing gas, for example, a C-containing gas can be used. As the C-containing gas, for example, a hydrocarbon-based gas such as a propylene (C₃H₆) gas, an ethylene (C₂H₄) gas, or an acetylene (C₂H₂) gas can be used. One or more of these gases can be used as the predetermined element-containing gas.

[Step A3]

After step A2 is completed, an O-containing gas is supplied to the wafers 200 in the processing chamber 201, that is, to the SiC layer formed on the wafers 200.

Specifically, the valve 243b is opened to cause the O-containing gas to flow into the gas supply pipe 232b. A flow rate of the O-containing gas is regulated by the MFC 241b, and the O-containing gas is supplied into the processing chamber 201 via the nozzle 249b and exhausted from the exhaust port 231a. At this time, the O-containing gas is supplied to the wafers 200 from a lateral side of the wafers 200 (O-containing gas supply). At this time, while the valves 243e and 243f are kept open, an inert gas may be supplied into the processing chamber 201 via the nozzles 249a and 249b, respectively.

As processing conditions in this step,

processing pressure: 1 to 4000 Pa, preferably 1 to 3000 Pa,

O-containing gas supply flow rate: 0.1 to 10 slm, and

O-containing gas supply time: 1 to 120 seconds, preferably 1 to 60 seconds

are exemplified. The other processing conditions are similar to the processing conditions at the time of supplying the source gas in step A1.

By supplying the O-containing gas to the wafers 200 under the above-described conditions, at least a part of the SiC layer formed on the wafers 200 is oxidized (modified). As a result, on an outermost surface of the wafers 200 serving as a base, a silicon oxycarbide layer (SiOC layer) is formed as a layer formed by oxidizing the SiC layer, that is, as a layer containing Si, O, and C. When the SiOC layer is formed, impurities contained in the SiC layer, such as Cl, constitute a gaseous substance containing at least Cl in the process of the modification reaction of the SiC layer by the O-containing gas, and are discharged from the inside of the processing chamber 201. As a result, the SiOC layer becomes a layer containing less impurities such as Cl than the SiC layer.

After the SiOC layer is formed, the valve 243b is closed, the supply of the O-containing gas into the processing chamber 201 is stopped, and a gas and the like remaining in the processing chamber 201 are removed from the inside of the processing chamber 201 by processing procedures similar to the purge in step A1 (purge).

As the O-containing gas, for example, an oxygen (O₂) gas, an ozone (O₃) gas, a water vapor (H₂O gas), a nitrogen monoxide (NO) gas, or a nitrous oxide (N₂O) gas can be used. One or more of these gases can be used as the O-containing gas. The same applies to step b described later.

[Step A4]

After step A3 is completed, a N-containing gas is supplied to the wafers 200 in the processing chamber 201, that is, to the SiOC layer formed on the wafers 200.

Specifically, the valve 243d is opened to cause the N-containing gas to flow into the gas supply pipe 232d. A flow rate of the N-containing gas is regulated by the MFC 241d, and the N-containing gas is supplied into the processing chamber 201 via the nozzle 249b and exhausted from the exhaust port 231a. At this time, the N-containing gas is supplied to the wafers 200 from a lateral side of the wafers 200 (N-containing gas supply). At this time, while the valves 243e and 243f are kept open, an inert gas may be supplied into the processing chamber 201 via the nozzles 249a and 249b, respectively.

As processing conditions in this step,

processing pressure: 1 to 4000 Pa, preferably 1 to 3000 Pa,

N-containing gas supply flow rate: 0.1 to 10 slm, and

N-containing gas supply time: 1 to 120 seconds, preferably 1 to 60 seconds

are exemplified. The other processing conditions are similar to the processing conditions at the time of supplying the source gas in step A1.

By supplying the N-containing gas to the wafers 200 under the above-described conditions, at least a part of the SiOC layer formed on the wafers 200 is nitrided (modified). As a result, on an outermost surface of the wafers 200 serving as a base, a silicon oxycarbonitride layer (SiOCN layer) is formed as a layer formed by nitriding the SiOC layer, that is, as a layer containing Si, O, C, and N. When the SiOCN layer is formed, impurities contained in the SiOC layer, such as Cl, constitute a gaseous substance containing at least Cl in the process of the modification reaction of the SiOC layer by the N-containing gas, and are discharged from the inside of the processing chamber 201. As a result, the SiOCN layer becomes a layer containing less impurities such as Cl than the SiOC layer.

After the SiOCN layer is formed, the valve 243d is closed, the supply of the N-containing gas into the processing chamber 201 is stopped, and a gas and the like remaining in the processing chamber 201 are removed from the inside of the processing chamber 201 by processing procedures similar to the purge in step A1 (purge).

As the N-containing gas, a hydrogen nitride-based gas such as an ammonia (NH₃) gas, a diazene (N₂H₂) gas, a hydrazine (N₂H₄) gas, or a N₃H₈ gas can be used. One or more of these gases can be used as the N-containing gas. The same applies to step a2 described later.

[Cycle is Performed a Predetermined Number of Times]

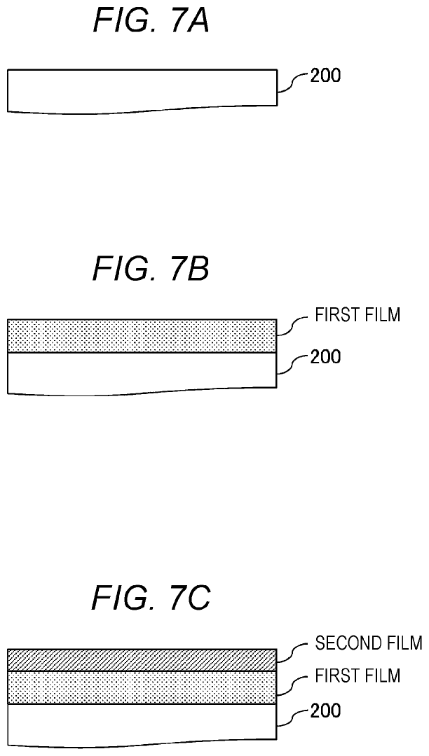

By performing a cycle of non-simultaneously, that is, non-synchronously performing the above-described steps A1 to A4 a predetermined number of times (n times, n is an integer of 1 or more), it is possible to form, as the first film, for example, a silicon oxycarbonitride film (SiOCN film) having a predetermined thickness and containing 0, N, for example, C as a predetermined element, and for example, Si as a semiconductor element on a surface of the wafers 200 serving as a base (see FIGS. 7A and 7B). The above-described cycle is preferably repeated a plurality of times. That is, the above-described cycle is preferably repeated a plurality of times until the thickness of the SiOCN film formed by making the thickness of the SiOCN layer formed per cycle smaller than a desired film thickness and laminating the SiOCN layer becomes a desired thickness.

(Second Film Forming)

Thereafter, the following steps a1 and a2 are sequentially executed.

[Step a1]

In step a1, a source gas is supplied to the wafers 200 in the processing chamber 201, that is, to the first film formed on the wafers 200 according to processing procedures and processing conditions similar to those in step A1 described above (source gas supply). As a result, a Si-containing layer is formed on the first film. After the Si-containing layer is formed, the supply of the source gas into the processing chamber 201 is stopped, and a gas and the like remaining in the processing chamber 201 are removed from the inside of the processing chamber 201 by processing procedures similar to the purge in step A1 (purge).

[Step a2]

After step a1 is completed, a N-containing gas is supplied to the wafers 200 in the processing chamber 201, that is, to the Si-containing layer formed on the first film on the wafers 200 according to processing procedures and processing conditions similar to those in step A1 described above (N-containing gas supply). As a result, at least a part of the Si-containing layer formed on the first film is nitrided (modified). As a result, on the first film serving as a base, a silicon nitride layer (SiN layer) is formed as a layer formed by nitriding the Si-containing layer, that is, as a layer containing Si and N. When the SiN layer is formed, impurities contained in the Si-containing layer, such as Cl, constitute a gaseous substance containing at least Cl in the process of the modification reaction of the SiN layer by the N-containing gas, and are discharged from the inside of the processing chamber 201. As a result, the SiN layer becomes a layer containing less impurities such as Cl than the Si-containing layer.

After the SiN layer is formed, the supply of the N-containing gas into the processing chamber 201 is stopped, and a gas and the like remaining in the processing chamber 201 are removed from the inside of the processing chamber 201 by processing procedures similar to the purge in step A1 (purge).

[Cycle is Performed a Predetermined Number of Times]

By performing a cycle of non-simultaneously, that is, non-synchronously performing the above-described steps a1 and a2 a predetermined number of times (m times, m is an integer of 1 or more), it is possible to form, as the second film, for example, a silicon nitride film (SiN film) having a predetermined thickness and containing N and, for example, Si as a semiconductor element on a surface of the first film serving as a base (see FIG. 7C).

The second film is a film that does not substantially contain O and the predetermined element contained in the first film, and has a component and a composition different from those of the first film. The above-described cycle is preferably repeated a plurality of times. That is, the above-described cycle is preferably repeated a plurality of times until the thickness of the SiN film formed by making the thickness of the SiN layer formed per cycle smaller than a desired film thickness and laminating the SiN layer becomes a desired thickness.

The thickness of the second film formed by the above-described processing procedures and processing conditions is smaller than the thickness of the first film serving as a base of the second film.

(After Purge and Return to Atmospheric Pressure)

After the processing of forming the laminated film formed by laminating the first film and the second film each having a desired thickness on the wafers 200 is completed, an inert gas is supplied as a purge gas from each of the nozzles 249a and 249b into the processing chamber 201 and is exhausted from the exhaust port 231a. As a result, the inside of the processing chamber 201 is purged, and a gas remaining in the processing chamber 201, a reaction by-product, and the like are removed from the inside of the processing chamber 201 (after purge). Thereafter, the atmosphere in the processing chamber 201 is replaced with an inert gas (inert gas replacement), and the pressure in the processing chamber 201 is returned to a normal pressure (return to atmospheric pressure).

(Boat Unload)

Thereafter, the seal cap 219 is lowered by the boat elevator 115, and a lower end of the manifold 209 is opened. Then, the processed wafers 200 are unloaded to the outside of the reaction tube 203 from the lower end of the manifold 209 in a state of being supported by the boat 217 (boat unload). After the boat unload, the shutter 219s is moved, and the lower end opening of the manifold 209 is sealed with the shutter 219s via the O-ring 220c (shutter close).

(Wafer Discharge)

After the wafers are cooled, the processed wafers 200 cooled to a predetermined temperature at which the wafers can be taken out are taken out of the boat 217 (wafer discharge).

In this way, the processing of forming the laminated film formed by laminating the first film and the second film on the wafers 200 is completed. This processing is performed a predetermined number of times (one or more times).

(2-2) Modification of Laminated Film

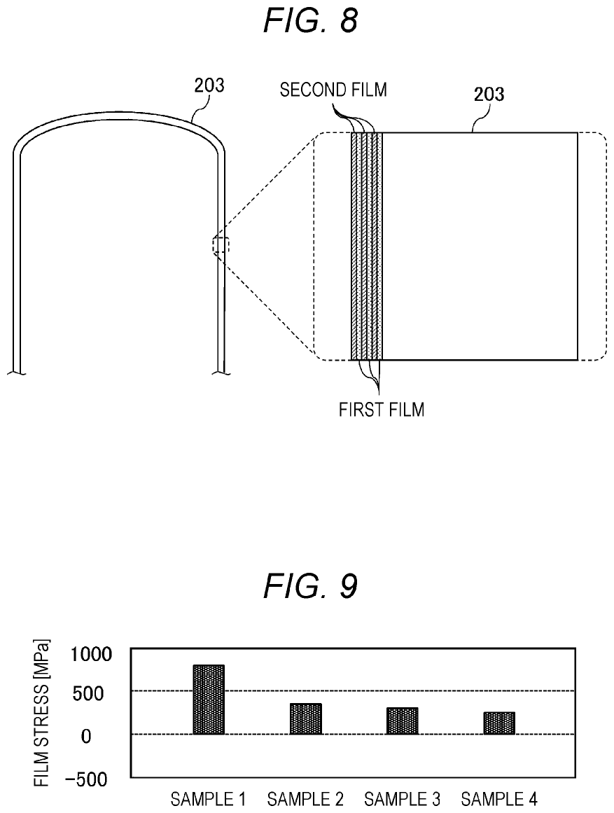

When the first film forming and the second film forming described above are performed, the laminated film of the first film and the second film also adheres to a surface of a member in the processing container, for example, an inner wall surface of the reaction tube 203, a surface of the boat 217, or the like. FIG. 8 schematically illustrates a partially enlarged cross-sectional view of an inner wall of the processing container to which the laminated film formed by alternately laminating the first film and the second film adheres by alternately and repeatedly performing the first film forming and the second film forming, that is, an inner wall of the reaction tube 203. Since a stress generated in a film is different between the first film and the second film, a crack is generated in the laminated film due to the difference in film stress between the first film and the second film by performing the processing of forming the laminated film, the film is peeled off from a surface of a member, and foreign matters (particles) may be generated in the furnace. Therefore, after the laminated film is formed, the laminated film adhering to the inside of the processing container is modified at a predetermined timing, and maintenance of reducing (alleviating) a difference in film stress between the first film and the second film is performed.

Hereinafter, the modification of the laminated film adhering to the inside of the processing container will be described. In the following description, operations of the units constituting the substrate processing apparatus are controlled by the controller 121.

(Empty Boat Load)

The shutter 219s is moved by the shutter opening/closing mechanism 115s, and a lower end opening of the manifold 209 is opened (shutter open). Thereafter, the empty boat 217 having the second film adhering to a surface thereof, that is, the boat 217 not holding the wafers 200 is lifted up by the boat elevator 115 and loaded into the processing container having the second film adhering to a surface thereof, that is, into the processing chamber 201 (empty boat load). In this state, the seal cap 219 seals a lower end of the manifold 209 via the O-ring 220b.

(Pressure Regulating and Temperature Regulating)

After the empty boat load is completed, the inside of the processing chamber 201 is vacuum-exhausted (decompression-exhausted) by the vacuum pump 246 so as to have a desired pressure (degree of vacuum). At this time, a pressure in the processing chamber 201 is measured by the pressure sensor 245, and the APC valve 244 is feedback-controlled based on the measured pressure information (pressure regulating). The inside of the processing chamber 201 is heated by the heater 207 so as to have a predetermined processing temperature. At this time, a degree of energization to the heater 207 is feedback-controlled based on temperature information detected by the temperature sensor 263 such that the inside of the processing chamber 201 has a predetermined temperature distribution (temperature regulating). Rotation of the empty boat 217 by the rotation mechanism 254 is started. The operation of the vacuum pump 246, the heating of the inside of the processing chamber 201, and the rotation of the boat 217 are all continuously performed until the modification of the laminated film is completed. Note that the boat 217 does not have to be rotated.

(Modification)

Thereafter, the following step b is executed.

[Step b]

In step b, for example, an O-containing gas is supplied to the laminated film in the processing container by processing procedures similar to the processing procedures in step A3 described above (O-containing gas supply). As a result, the laminated film in the processing container is oxidized. After the oxidation is completed, the supply of the source gas into the processing chamber 201 is stopped, and a gas and the like remaining in the processing chamber 201 are removed from the inside of the processing chamber 201 by processing procedures similar to the purge in step A1 (purge).

As processing conditions in this step,

processing temperature: 300 to 750° C., preferably 500 to 650° C.,

processing pressure: 30 to 1200 Pa, preferably 1000 to 1200 Pa,

O-containing gas supply flow rate: 1 to 10 slm, preferably 3 to 6 slm, and

O-containing gas supply time: 10 to 60 minutes, preferably 20 to 40 minutes

are exemplified. The other processing conditions are similar to the processing conditions at the time of supplying the source gas in step A1.

By supplying the O-containing gas to the laminated film in the processing container under the above-described conditions, at least a part of either the first film (SiOCN film) or the second film (SiN film) in the laminated film is oxidized (modified). Specifically, by supplying the O-containing gas into the processing container, the second film is oxidized to be modified to a silicon oxynitride film (SiON film), and the first film is oxidized to further incorporate O into the first film to be modified to a SiOCN film having a high O concentration (oxygen rich). In this way, by bringing the composition of the second film close to the composition of the first film, the difference in film stress between the first film and the second film can be reduced.

When the processing temperature is lower than 300° C., activation of the O-containing gas may be insufficient, and a progress of the modification (oxidation) may be difficult. When the processing temperature is 300° C. or higher, activation of the O-containing gas is sufficient, and the modification (oxidation) can be advanced. When the processing temperature is 500° C. or higher, the O-containing gas can be further activated, and the modification (oxidation) can be efficiently performed.

When the processing temperature is higher than 750° C., activation of the O-containing gas may be excessive, and a progress of the modification (oxidation) may be difficult. When the processing temperature is 750° C. or lower, activity of the O-containing gas can be appropriately suppressed, and the modification (oxidation) can be advanced. When the processing temperature is 650° C. or lower, activation of the O-containing gas can be more appropriately suppressed, and the modification (oxidation) can be efficiently performed.

When the processing pressure is less than 30 Pa, activation of the O-containing gas may be insufficient, and a progress of the modification (oxidation) may be difficult. When the processing pressure is 30 Pa or more, activation of the O-containing gas is sufficient, and the modification (oxidation) can be advanced. When the processing pressure is 1000 Pa or more, the O-containing gas can be further activated, and the modification (oxidation) can be efficiently performed.

When the processing pressure is more than 1200 Pa, activation of the O-containing gas may be excessive, and a progress of the modification (oxidation) may be difficult. When the processing pressure is 1200 Pa or less, activity of the O-containing gas can be appropriately suppressed, and the modification (oxidation) can be advanced.

When the O-containing gas supply flow rate is less than 1 slm, a progress of the modification (oxidation) may be difficult. When the O-containing gas supply flow rate is 1 slm or more, the modification (oxidation) can be advanced. When the O-containing gas supply flow rate is 3 slm or more, the modification (oxidation) can be efficiently performed. When the O-containing gas supply flow rate is more than 10 slm, the modification (oxidation) may be excessively advanced. In addition, gas cost may be increased. When the O-containing gas supply flow rate is 10 slm or less, an excessive progress of the modification (oxidation) can be suppressed, and an increase in gas cost can be avoided. When the O-containing gas supply flow rate is 6 slm or less, an excessive progress of the modification (oxidation) can be more appropriately suppressed, and an increase in gas cost can be more reliably avoided.

When the O-containing gas supply time is less than 10 minutes, a progress of the modification (oxidation) may be difficult. When the O-containing gas supply time is 10 minutes or more, the modification (oxidation) can be advanced. When the O-containing gas supply time is 20 minutes or more, the modification (oxidation) can be efficiently performed.

When the O-containing gas supply time is more than 60 minutes, the modification (oxidation) may be excessively advanced. In addition, productivity may be decreased. When the O-containing gas supply time is 60 minutes or less, an excessive progress of the modification (oxidation) can be suppressed, and a decrease in productivity can be avoided. When the O-containing gas supply time is 40 minutes or less, an excessive progress of the modification (oxidation) can be more appropriately suppressed, and a decrease in productivity can be more reliably avoided.

(After Purge and Return to Atmospheric Pressure)

After the modification (oxidation) of the laminated film in the processing container is completed, an inert gas is supplied as a purge gas from each of the nozzles 249a and 249b into the processing chamber 201 and is exhausted from the exhaust port 231a. As a result, the inside of the processing chamber 201 is purged, and a gas remaining in the processing chamber 201, a reaction by-product, and the like are removed from the inside of the processing chamber 201 (after purge). Thereafter, the atmosphere in the processing chamber 201 is replaced with an inert gas (inert gas replacement), and the pressure in the processing chamber 201 is returned to a normal pressure (return to atmospheric pressure).

(Empty Boat Unload)

Thereafter, the seal cap 219 is lowered by the boat elevator 115, and a lower end of the manifold 209 is opened. Then, the empty boat 217 is unloaded to the outside of the reaction tube 203 from the lower end of the manifold 209 (boat unload). After the boat unload, the shutter 219s is moved, and the lower end opening of the manifold 209 is sealed with the shutter 219s via the O-ring 220c (shutter close).

In this way, the modification of the laminated film formed by laminating the first film and the second film adhering to the inside of the processing container is completed. This processing may be performed every time the first film forming and the second film forming are each performed once, or may be performed every time the first film forming and the second film forming are each performed twice or more (a plurality of times).

(3) Effects of the Present Embodiments

According to the present embodiments, one or more of the following effects can be obtained.

In step B, by performing the modification that brings the composition of the second film in the laminated film adhering to the inside of the processing container close to the composition of the first film, a difference in film stress between the first film and the second film can be made smaller than a difference in film stress between the first film and the second film before step B is performed. As a result, the laminated film adhering to the inside of the processing container is less likely to be peeled off, and generation of particles can be suppressed. As a result, the quality of the film formed on the wafer 200 can be improved, and a yield rate can be largely improved. In addition, by suppressing occurrence of film peeling, a frequency of cleaning can be decreased, and downtime of the substrate processing apparatus can be shortened. By the decrease in frequency of cleaning, in the first film forming performed thereafter, it is possible to avoid deterioration of the quality of a film formed on the wafer 200 due to mixing of a component of a cleaning gas desorbed from an inner wall or the like of the processing container into the film.

(b) In step B, by supplying an O-containing gas into the processing container and performing the modification (oxidation), the film stress in each of the first film and the second film can be reduced. Specifically, since the film stress of the second film having a film stress larger than that of the first film can be more largely reduced, the difference in film stress between the first film and the second film can be reduced. In addition, in step B, by performing the modification (oxidation) using a gas containing O contained in the first film (O-containing gas), it is possible to prevent occurrence of contamination of the gas supplied into the processing container.

(c) By forming the second film with a thickness smaller than the thickness of the first film, the first film can be used as an interlayer insulating film, and the second film can be used as a cap film.

(d) When step B (modification) is performed every time step A (each of the first film forming and the second film forming) is performed once, it is possible to reliably reduce a difference in film stress between the first film and the second film in the laminated film adhering to the inside of the processing container.

(e) When step B (modification) is performed every time step A (each of the first film forming and the second film forming) is performed twice or more, it is possible to reduce a difference in film stress between the first film and the second film in the laminated film adhering to the inside of the processing container without substantially decreasing a throughput.

(f) By performing step A in a state where the boat 217 supporting the wafers 200 is housed in the processing container and performing step B in a state where the boat 217 not supporting the wafers 200 is housed in the processing container, it is possible to reduce a difference in film stress between the first film and the second film in the laminated film adhering to the inside of the boat 217 or the processing container without adversely affecting the laminated film formed on the wafers 200.

<Other Embodiments of the Present Disclosure>

Hereinabove, the embodiments of the present disclosure has been described in detail, but the present disclosure is not limited to the above-described embodiments, and various modifications can be made without departing from the gist of the present disclosure.

In the above-described embodiments, an example has been described in which a film containing a semiconductor element (Si) is formed as each of the first film and the second film, but the present disclosure is not limited thereto. For example, the present disclosure can also be applied to a case where a film containing a metal element such as aluminum (Al), titanium (Ti), hafnium (Hf), zirconium (Zr), tantalum (Ta), niobium (Nb), molybdenum (Mo), or tungsten (W) is formed as each of the first film and the second film. Also in this case, effects similar to those of the above-described embodiments can be obtained.

In the above-described embodiments, an example has been described in which C is used as the predetermined element and the SiOCN film is formed as the first film containing the predetermined element, but the present disclosure is not limited thereto. For example, the present disclosure can also be applied to a case where a silicon borate oxynitride film (SiBON film) is formed as the first film using B as the predetermined element and using a B-containing gas such as a diborane (B₂H₆) gas or a trichloroborane (BCl₃) gas as the predetermined element-containing gas. In addition, for example, the present disclosure can also be applied to a case where a silicon borate oxycarbonitride film (SiBOCN film) is formed as the first film using a gas containing C and B as the predetermined elements. Also in these cases, effects similar to those of the above-described embodiments can be obtained.

In the above-described embodiments, an example has been described in which a laminated film formed by laminating the first film and the second film is formed on the same wafer 200, but the present disclosure is not limited thereto. For example, the present disclosure can also be applied to a case where the first film and the second film are formed on different wafers 200. Also in this case, effects similar to those of the above-described embodiments can be obtained.

Preferably, the recipe used in each processing is individually prepared according to processing contents and stored in the memory 121c via an electric communication line or the external memory 123. Then, when each processing is started, the CPU 121a preferably appropriately selects an appropriate recipe from among the plurality of recipes stored in the memory 121c according to processing contents. As a result, it is possible to form films having various film types, composition ratios, film qualities, and film thicknesses with good reproducibility by using one substrate processing apparatus. In addition, it is possible to reduce a burden on an operator, and it is possible to quickly start each processing while avoiding an operation error.

The above-described recipe is not limited to a newly created one, and may be prepared by changing the existing recipe already installed in the substrate processing apparatus, for example. In the case of changing the recipe, the changed recipe may be installed in the substrate processing apparatus via an electric communication line or a recording medium in which the recipe is recorded. In addition, the input/output device 122 of the existing substrate processing apparatus may be operated, and the existing recipe previously installed in the substrate processing apparatus may be directly changed.

In the above-described embodiments, an example has been described in which a film is formed using the batch type substrate processing apparatus that processes a plurality of substrates at a time. The present disclosure is not limited to the above-described embodiments, and can be preferably applied to a case where a film is formed using a single wafer type substrate processing apparatus that processes one or more substrates at a time, for example. In the above-described embodiments, an example has been described in which a film is formed using a substrate processing apparatus having a hot wall type processing furnace. The present disclosure is not limited to the above-described embodiments, and can be preferably applied to a case where a film is formed using a substrate processing apparatus having a cold wall type processing furnace.

Even when such a substrate processing apparatus is used, each processing can be performed according to processing procedures and process conditions similar to those in the above-described embodiments, and effects similar to those in the above-described embodiments can be obtained.

The above-described embodiments can be used in combination as appropriate. Processing procedures and processing conditions at this time can be similar to the processing procedures and the processing conditions in the above-described embodiments, for example.

### EXAMPLES

By performing the following first processing using the substrate processing apparatus according to the above-described embodiments, a laminated film formed by laminating a SiOCN film and a SiN film was formed on a plurality of wafers. In addition, by performing the following second processing, the above-described laminated film was formed on the plurality of wafers and was oxidized (modified). In the SiOCN film, an HCDS gas was used as the source gas, a C₃H₆ gas was used as the predetermined element-containing gas, an O₂ gas was used as the O-containing gas, and an NH₃ gas was used as then N-containing gas. In the SiN film, an HCDS gas and an NH₃ gas were used as the source gas and the N-containing gas, respectively, similarly to the SiOCN film. In the oxidation (modification), an O₂ gas was used as the O-containing gas. The other processing conditions were common conditions within the processing condition range in the above-described embodiments.

First processing: (source gas→predetermined element-containing gas→O-containing gas→N-containing gas)×n→(source gas→N-containing gas)×m

Second processing: (source gas→predetermined element-containing gas→O-containing gas→N-containing gas)×n→(source gas→N-containing gas)×m→O-containing gas

The SiN film and the SiOCN film in the laminated film formed by performing the first processing were referred to as sample 1 and sample 2, respectively. The SiON film modified by oxidizing the SiN film in the laminated film by performing the second processing was referred to as sample 3, and the SiOCN film further incorporating O was referred to as sample 4.

Film stresses in samples 1 to 4 were measured. Results thereof are illustrated in FIG. 9. The horizontal axis indicates each of the samples. The vertical axis indicates a film stress [MPa]. On the vertical axis, a positive stress means a tensile stress, and a negative stress means a compressive stress.

As illustrated in FIG. 9, it was confirmed that the film stresses in samples 1 to 4 were tensile stresses of about 800 MPa, 280 MPa, 250 MPa, and 230 MPa, respectively. That is, it was confirmed that the film stress was largely reduced (from about 800 MPa to about 250 MPa) by oxidizing the laminated film to modify the SiN film to the SiON film. In addition, it was confirmed that the film stress was reduced (from about 280 MPa to about 230 MPa) by oxidizing the laminated film to further incorporating O into the SiOCN film. In addition, it was confirmed that the difference in film stress between the SiON film (sample 3) and the SiOCN film (sample 4) could be made smaller than the difference in film stress between the SiN film (sample 1) and the SiOCN film (sample 2) before the oxidation by oxidizing the laminated film to modify the SiN film to the SiON film, and bringing the composition thereof close to the composition of the SiOCN film.

In addition, a composition ratio of each of the films of samples 1 to 4, that is, concentrations of Si, O, C, N, and the like contained in each of the films was measured by X-ray photoelectron spectroscopy (XPS). In sample 3 (SiON film), it was confirmed that the O concentration was higher, the Si concentration was lower, and the N concentration was lower as compared with sample 1 (SiN film). In sample 4 (SiOCN film), it was confirmed that the O concentration was higher, the Si concentration and the C concentration were lower, and the N concentration was unchanged as compared with sample 2 (SiOCN film). In sample 2 (SiOCN film), it was confirmed that the O concentration was higher, the Si concentration was lower, and the N concentration was lower as compared with sample 1 (SiN film). In sample 4 (SiOCN film), it was confirmed that the O concentration was higher, the Si concentration was almost equal, the C concentration was higher, and the N concentration was lower as compared with sample 3 (SiON film).

In addition, it was confirmed that the difference in Si concentration between sample 3 (SiON film) and sample 4 (SiOCN film) was smaller as compared with the difference in Si concentration between sample 1 (SiN film) and sample 2 (SiOCN film). It was confirmed that the difference in O concentration between sample 3 (SiON film) and sample 4 (SiOC N film) was smaller as compared with the difference in O concentration between sample 1 (SiN film) and sample 2 (SiOCN film). It was confirmed that the difference in C concentration between sample 3 (SiON film) and sample 4 (SiOCN film) was smaller as compared with the difference in C concentration between sample 1 (SiN film) and sample 2 (SiOCN film). It was confirmed that the difference in N concentration between sample 3 (SiON film) and sample 4 (SiOCN film) was smaller as compared with the difference in N concentration between sample 1 (SiN film) and sample 2 (SiOCN film).

In addition, it was confirmed that N concentration>Si concentration>O concentration was satisfied in sample 1 (SiN film), and Si concentration>N concentration>O concentration was satisfied in sample 3 (SiON film) after the modification. As described above, in sample 1 (SiN film) and sample 3 (SiON film), the order of the N concentration and the Si concentration was reversed. In addition, it was confirmed that Si concentration>O concentration>N concentration>C concentration was satisfied in sample 2 (SiOCN film), and Si concentration>O concentration>N concentration>C concentration was satisfied also in sample 4 (SiOCN film) after the modification without change in the order.

As described above, in both the SiN film and the SiOCN film in the laminated film, it was confirmed that the O concentration was increased by performing the oxidation. For example, it was confirmed that the O concentration was increased from 28 at % to 31 at % by performing the oxidation in the SiOCN film (sample 2) in the laminated film, and the O concentration was increased from 3 at % to 21 at % by performing the oxidation in the SiN film (sample 1) in the laminated film. In addition, it was confirmed that, by performing the oxidation, the difference in concentration of each of Si, O, C, and N between the films after the oxidation was smaller than that between the films before the oxidation. As described above, it was confirmed that the composition of sample 1 (SiN film) was modified to be closer to the composition of sample 2 (SiOCN film) by the oxidation.

According to the present disclosure, it is possible to suppress occurrence of film peeling of a laminated film adhering to the inside of the processing container.

FIG. 3
123 External Memory
122 Input/Output Device
121c Memory
121d I/O Port
243a TO 243f Valve
245 Pressure Sensor
244 APC Valve
246 Vacuum Pump
207 Heater
263 Temperature Sensor
267 Rotation Mechanism
115 Boat Elevator
115s Shutter Opening/Closing Mechanism

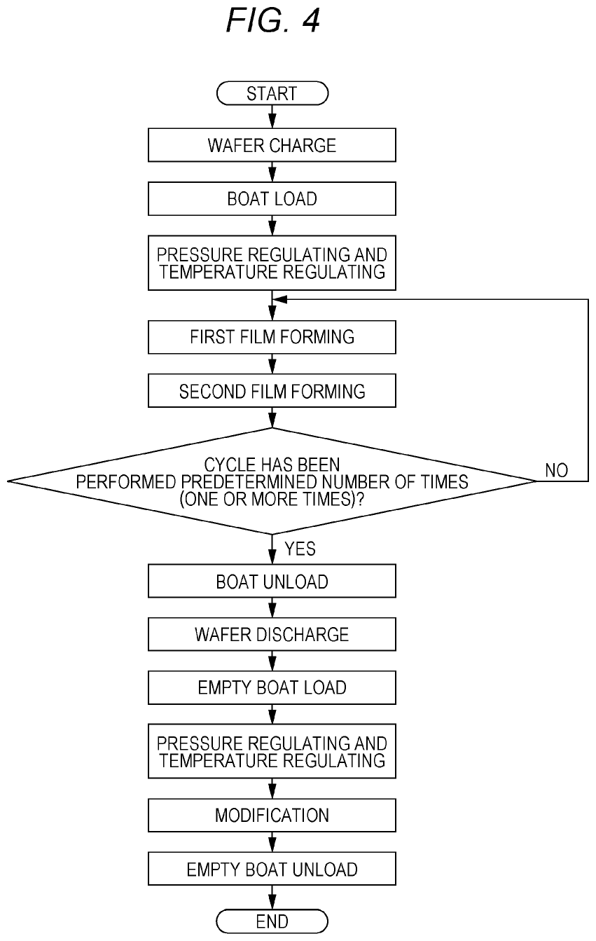

FIG. 4
Start
Wafer Charge
Boat Load
Pressure Regulating and Temperature Regulating
First Film Forming
Second Film Forming
Cycle has been Performed Predetermined Number of Times (One or
More Times)?
Boat Unload
Wafer Discharge
Empty Boat Load
Pressure Regulating and Temperature Regulating
Modification
Empty Boat Unload
End

FIG. 5
Source Gas
Predetermined Element-Containing Gas
Oxygen-Containing Gas
Nitrogen-Containing Gas
Inert Gas

FIG. 6
Source Gas
Nitrogen-Containing Gas
Inert Gas

FIG. 7B
First Film

FIG. 7C
Second Film
First Film

FIG. 8
Second Film
First Film

FIG. 9
Film Stress
Sample 1
Sample 2
Sample 3
Sample 4

1. A method of processing a substrate, comprising:
(a) forming a laminated film formed by laminating a first film containing nitrogen, oxygen, and a predetermined element and a second film containing nitrogen and having a composition different from that of the first film on a substrate in a processing container; and
(b) modifying the first film and the second film adhering to an inside of the processing container in (a) to bring the composition of the second film adhering to the inside of the processing container close to the composition of the first film adhering to the inside of the processing container.

2. The method according to claim 1, wherein
the modification is an oxidation of supplying an oxygen-containing gas into the processing container.

3. The method according to claim 1, wherein
a difference in film stress between the first film and the second film adhering to the inside of the processing container after (b) is smaller than a difference in film stress between the first film and the second film adhering to the inside of the processing container before (b).

4. The method according to claim 1, wherein
each of the first film and the second film further contains at least one of a semiconductor element and a metal element.

5. The method according to claim 1, wherein
the predetermined element is at least one of carbon and boron.

6. The method according to claim 1, wherein
the first film is a SiOCN film or a SiBON film.

7. The method according to claim 6, wherein the second film is a SiN film.

8. The method according to claim 1, wherein
an oxygen concentration in the first film adhering to the inside of the processing container after (b) is performed is higher than an oxygen concentration in the first film adhering to the inside of the processing container before (b).

9. The method according to claim 1, wherein
the second film adheres to the inside of the processing container with a thickness smaller than the thickness of the first film adhering to the inside of the processing container in (a).

10. The method according to claim 1, wherein
(b) is performed every time (a) is performed once.

11. The method according to claim 1, wherein
(b) is performed every time (a) is performed two or more times.

12. The method according to claim 1, wherein
(a) is performed in a state where a substrate support supporting the substrate is housed in the processing container, and (b) is performed in a state where the support not supporting the substrate after (a) is housed in the processing container.

13. The method according to claim 1, wherein
the second film adhering to the inside of the processing container before (b) neither contains oxygen nor the predetermined element.

14. The method according to claim 1, wherein
a difference in nitrogen concentration between the first film and the second film adhering to the inside of the processing container after (b) is smaller than a difference in nitrogen concentration between the first film and the second film adhering to the inside of the processing container before (b).

15. The method according to claim 1, wherein
a difference in oxygen concentration between the first film and the second film adhering to the inside of the processing container after (b) is smaller than a difference in oxygen concentration between the first film and the second film adhering to the inside of the processing container before (b).

16. The method according to claim 1, wherein
a difference in concentration of the predetermined element between the first film and the second film adhering to the inside of the processing container after (b) is smaller than a difference in concentration of the predetermined element between the first film and the second film adhering to the inside of the processing container before (b).

17. The method according to claim 1, wherein
the second film further contains silicon, a silicon concentration in the second film adhering to the inside of the processing container before (b) is lower than a nitrogen concentration, and the silicon concentration in the second film adhering to the inside of the processing container after (b) is higher than the nitrogen concentration.

18. A method of manufacturing a semiconductor device, comprising the method according to claim 1.

19. A non-transitory computer-readable recording medium recording a program that causes, with a computer, a substrate processing apparatus to execute:
(a) forming a laminated film formed by laminating a first film containing nitrogen, oxygen, and a predetermined element and a second film containing nitrogen and having a composition different from that of the first film on a substrate in a processing container of the substrate processing apparatus; and
(b) modifying the first film and the second film adhering to an inside of the processing container in (a) to bring the composition of the second film adhering to the inside of the processing container close to the composition of the first film adhering to the inside of the processing container.

20. A substrate processing apparatus comprising:
a processing container in which a substrate is processed;
a processing gas supply system configured to supply a nitrogen-containing gas, an oxygen-containing gas, and a predetermined element-containing gas into the processing container; and
a controller configured to control the processing gas supply system to perform, in the processing container, (a) forming a laminated film formed by laminating a first film containing nitrogen, oxygen, and a predetermined element and a second film containing nitrogen and having a composition different from that of the first film on the substrate in the processing container, and (b) modifying the first film and the second film adhering to an inside of the processing container in (a) so as to bring the composition of the second film adhering to the inside of the processing container close to the composition of the first film adhering to the inside of the processing container.
